(19) United States
(12) Patent Application Publication
(10) Pub. No.: US 2025/0383390 A1
(43) Pub. Date: Dec. 18, 2025

(54) SIGNAL ACCESS EXTENDER APPARATUS

(71) Applicant: RSD Aviation Patent, LLC, Land O Lakes, FL (US)

(72) Inventor: Ronald James NELSON, Land O Lakes, FL (US)

(73) Assignee: RSD Aviation Patent, LLC, Land O Lakes, FL (US)

(21) Appl. No.: 18/741,067

(22) Filed: Jun. 12, 2024

(51) Int. Cl. G01R 31/00; H01R 12/79; H05K 7/14

(52) U.S. Cl. CPC G01R 31/008; H05K 7/1427; H01R 12/79

(57) ABSTRACT

A signal access extender apparatus includes a rackmount enclosure, a rackmount enclosure lid coupled to the rackmount enclosure, the rackmount enclosure and the rackmount enclosure lid defining a shape of the signal access extender apparatus, a printed circuit board inserted into a front end of the rackmount enclosure, a circuit function board included in the rackmount enclosure and coupled at one end of the circuit function board to a harness and at another end to the printed circuit board. The signal access extender apparatus is insertable into a compartment of a rack system to replace a unit in the compartment, the shape of the signal access extender apparatus being substantially the same as the unit being replaced and being such that the signal access extender apparatus fits within and substantially fills the compartment, the signal access extender apparatus electronically coupling to the harness and to the printed circuit board.

### BACKGROUND

### 1. Field

The present disclosure relates to signal output port access and, more specifically, to making signal output ports more accessible.

### 2. Description of the Related Art

It is sometimes necessary or desired to access signals output from a harness in a rack system which terminate at the rear side of a compartment of the rack system and are thus difficult to access. An example of such difficult to access ports would be include rack-mounted devices in which signal output is delivered by a harness to ports located at a rear side (or far side) of the rack-mounted device.

Therefore, an apparatus is needed to make signal output ports more accessible.

### SUMMARY

A signal access extender apparatus comprises a rackmount enclosure; a rackmount enclosure lid coupled to the rackmount enclosure, the rackmount enclosure and the rackmount enclosure lid defining a shape of the signal access extender apparatus; a printed circuit board inserted into a front end of the rackmount enclosure; a circuit function board included in the rackmount enclosure and coupled at one end of the circuit function board to a harness and at another end of the circuit function board to the printed circuit board, wherein the signal access extender apparatus being insertable into a compartment of a rack system to replace a unit in the compartment, the shape of the signal access extender apparatus being substantially the same as the unit being replaced and being such that the signal access extender apparatus fits within and substantially fills the compartment, the signal access extender apparatus electronically coupling to the harness and to the printed circuit board.

Additional aspects and/or advantages will be set forth in part in the description which follows and, in part, will be apparent from the description, or may be learned by practice of the invention.

### BRIEF DESCRIPTION OF THE DRAWINGS

These and/or other aspects and advantages will become apparent and more readily appreciated from the following description of the embodiments, taken in conjunction with the accompanying drawings of which:

FIG. 1 shows an example of signal access extender apparatus 10 of the present disclosure insertable into rack system 1.

FIGS. 2A, 2B, and 2C show examples of signal access extender apparatus 10 in various stages of being inserted into compartment 2 of rack 1 to provide access to harness 5.

FIG. 3 shows an example of a signal access extender apparatus 10 in accordance with the present disclosure.

FIG. 4 shows an example of a detailed view of signal access extender apparatus 10.

FIG. 5 shows a detailed view of an example of signal access extender apparatus 10 including an example of circuit function board 24.

FIG. 6 shows an example of an aircraft instrument panel 30 as a front end 3 of rack system 1.

FIG. 7 shows another example of an aircraft instrument panel 30 as a front end 3 of rack system 1.

### DETAILED DESCRIPTION

Reference will now be made in detail to the embodiments, examples of which are illustrated in the accompanying drawings, wherein like reference numerals refer to the like elements throughout. The embodiments are described below to explain the present invention by referring to the figures.

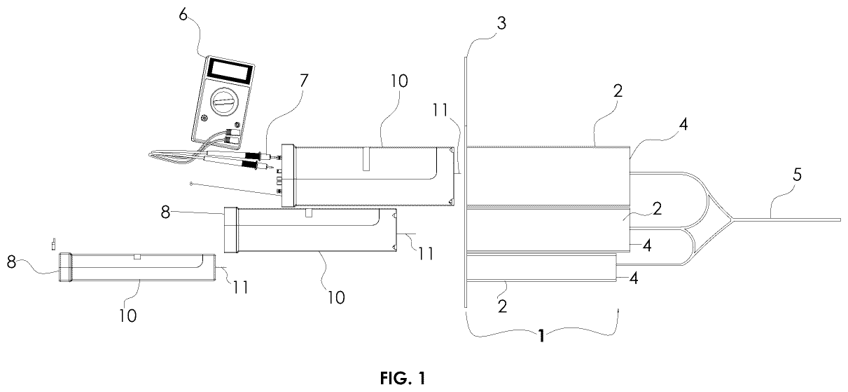

FIG. 1 shows an example of signal access extender apparatus 10 of the present disclosure insertable into rack system 1. In the example of FIG. 1, rack system 1, such as a factory avionics rack system, typically holds electronic units, such as avionics units, in individual compartments 2 during normal operation.

Rack system 1 may be a universal rack, such as an avionics rack housing a radio stack, electronics to determine and display air speed and other information, in which electronic boxes slide in and out of compartments 2. Compartments 2 may have a uniform shape for holding avionics units, such as slide-in radio units from manufacturers such as GARMIN AVIONICS. For example, compartment 2 may have a standard width of 6 inches, with a depth varying between 5 inches and 8 inches. However, compartment 2 is not limited to such dimensions of width and depth.

Referring again to FIG. 1, a front end 3 of the rack system 1 is typically uniform and exposed to and accessible by a user such as an aircraft instrument panel, whereas a back end of the individual compartments 2 may define a back end of the rack system 1 and such back end of the rack system 1 may vary in uniformity and be difficult to access by a user. Moreover, a harness 5, such as an avionics wire harness (or wiring harness), carrying electronic or other signals may be coupled to the back end 4 of each of the individual compartments, making it difficult for a user to access the harness 5 for signal testing or other purposes.

FIG. 1 also shows signal access extender apparatus 10 in accordance with the present disclosure. As shown in FIG. 1, each signal access extender apparatus 10 is inserted into a respective compartment 2 of rack system 1 to replace, temporarily, an electronic unit in compartment 2 so that signal access extender apparatus 10 may perform a function such as, for example, to check continuity of connections, such as electronic or electrical connections, in compartment 2. Each signal access extender apparatus 10 is form-fitted, or substantially form-fitted, to a corresponding, respective compartment 2 of rack system 1 to be held securely in place and to provide access to harness 5. As shown in FIG. 1, signal access extender apparatus 10 may include guide pin 11 to mate with compartment 2 and ensure proper placement of signal access extender apparatus 10 into compartment 2.

Signals carried by harness 5 can then be tested for continuity, for example, by a manual tester such as a digital multimeter 6 by inserting leads 7 into a front PCB (printed circuit board) 8 of signal access extender apparatus 10.

Compartment 2 may be, for example, part of an aircraft instrument panel of a factory avionics rack system 1 installed in a general aviation aircraft and may hold common general aviation electronics. However, rack system 1 is not limited to a factory avionics rack system in a general aviation aircraft, and may be installed in a corporate aircraft, a military aircraft, or in marine applications.

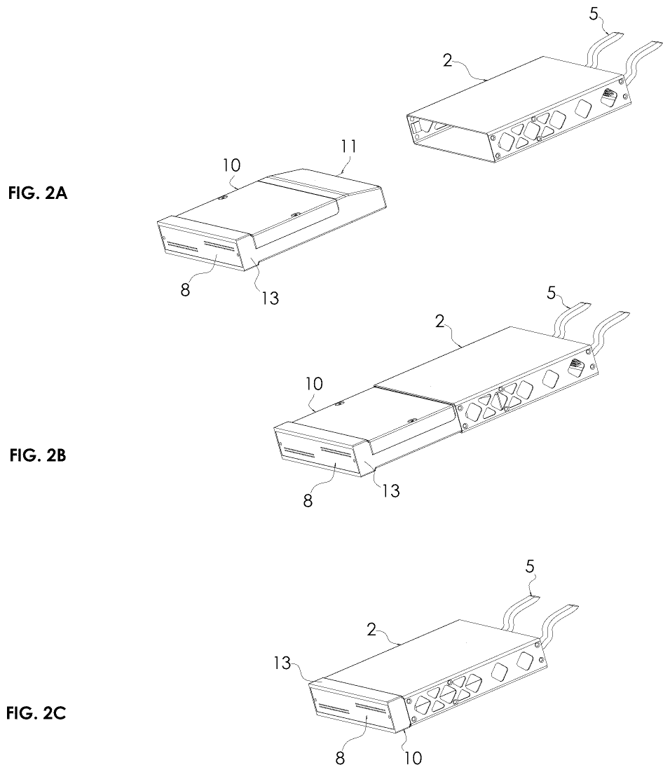

FIGS. 2A, 2B, and 2C show signal access extender apparatus 10 in various stages of being inserted into compartment 2 of rack 1 to provide access to harness 5. As shown in FIGS. 2A, 2B, and 2C, signal access extender apparatus 10 is form-fitted to compartment 2 to be held in place by compartment 2 and to provide access to harness 5. Also as shown in FIGS. 2A, 2B, and 2C, signal access extender apparatus 10 includes rim 13 at a front of signal access extender 10. As shown in FIGS. 2A, 2B, and 2C, rim 13 may contact with and extend from a front of compartment 2 when signal access extender apparatus 10 is fully inserted into compartment 2.

FIG. 2A shows signal access extender apparatus 10 of the present disclosure to be inserted into compartment 2 of rack 1 in place of an electronics unit, such as an avionics unit. FIG. 2B shows signal access extender apparatus 10 of the present disclosure partially inserted into compartment 2, while FIG. 2C shows signal access extender apparatus 10 of the present disclosure fully inserted into compartment 2.

In an example of FIGS. 2A, 2B, and 2C, signal access extender apparatus 10 is manually inserted into compartment 2.

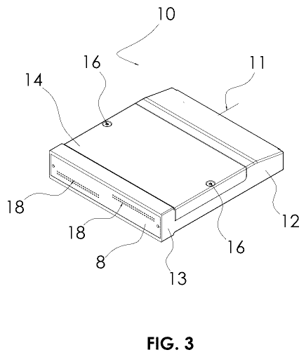

FIG. 3 shows an example of a signal access extender apparatus 10 in accordance with the present disclosure. As shown in FIG. 3, signal access extender apparatus 10 may include rackmount enclosure 12 and rackmount enclosure lid 14 fixed to rackmount enclosure 12 by fasteners 16. Rackmount enclosure 12 and rackmount enclosure lid 14 define a shape of signal access extender apparatus 10. Such shape of signal access extender apparatus 10 may be custom-defined or may have a standard shape related to avionics electronics, such as radio units from manufacturers such as GARMIN.

In the example of FIG. 3, a front of rackmount enclosure 12 includes rim (or collar) 13 which extends a profile of signal access extender apparatus 10 and may also extend signal access extender apparatus 10 from a front of compartment 2.

In the example of FIG. 3, signal access extender apparatus 10 may be a 3D printed nylon/carbon fiber enclosure, such as carbon-infused nylon. However, signal access extender apparatus 10 may be 3D printed, injection molded, metal fabricated, or a combination thereof, and may include materials in addition to or in place of carbon-infused nylon such as plastic or other materials.

Also as shown in FIG. 3, signal access extender apparatus 10 may include access ports 18 on front PCB (printed circuit board) 8 on a front side of signal access extender apparatus 10, as well as access ports (not shown in FIG. 3) on a rear side of signal access extender apparatus 10.

Signal access extender apparatus 10 may slide or be placed into, for example, an avionics rack in place of an avionics unit and mate with connectors in the avionics rack, similarly to the way in which the avionics unit mates with the connectors in the avionics rack, to transfer signals from the avionics rack to front PCB 8 of the signal access extender apparatus 10. Signal access extender apparatus 10 is held in place in compartment 2 of rack system 1 by the shape of signal access extender apparatus 10 being substantially of the same shape as the avionics unit or other unit which signal access extender apparatus 10 is replacing in compartment 2 and may be shaped to fit within and substantially fill compartment 2.

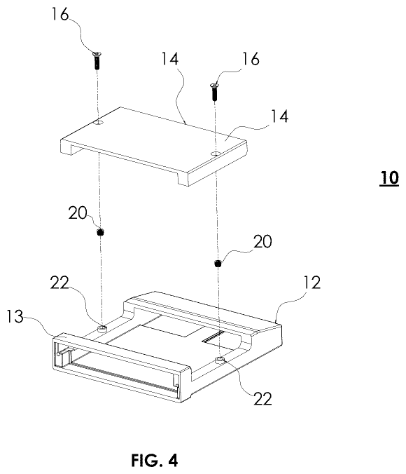

FIG. 4 shows an example of a detailed view of signal access extender apparatus 10. As shown in FIG. 4, rackmount enclosure lid 14 may be fixed to rackmount enclosure 12 by fasteners 16. In the example of FIG. 4, an example of fastener 16 is a black-oxide alloy steel hex drive flat head screw, M4×16 mm, part number MCMASTER 91294A194.

Also as shown in FIG. 4, fasteners 16 may fix rackmount enclosure lid 14 to rackmount enclosure 12 through inserts 20 and in contact with receptacles 22 in rackmount enclosure 12. In the example of FIG. 4, fasteners 16 are placed on each, parallel side of rackmount enclosure 14, in which at least one fastener 16 is placed on a front side of rackmount enclosure 12 and at least one fastener 16 is placed on a rear side of rackmount enclosure 12.

An example of insert 20 is a tapered heat-set insert, M4×4.7 mm length, part number MCMASTER 94180A351.

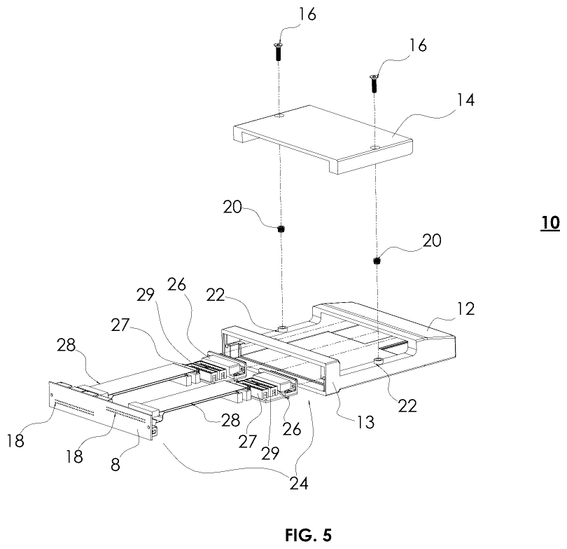

FIG. 5 shows a detailed view of an example of signal access extender apparatus 10 including circuit function board 24. In the example of the signal access extender apparatus 10, circuit function board 24 is a signal extender circuit board. However, circuit function board 24 is not limited to being a signal extender circuit board and may be a circuit board that performs functions other than and/or including functions similar to a signal access extender board. Moreover, such circuit function board 24 may be replaced by a user by removing rackmount enclosure lid 14 from rackmount enclosure 12, and replacing circuit function board 24. Functions of circuit board 24 included in signal access extender apparatus 10 may be used while signal access extender apparatus 10 is inserted into compartment 2 of rack system 1 or while harness 5 is plugged into circuit function board 24 on a test bed or test bench.

In the example of circuit function board 24 in the following disclosure, circuit function board 24 is referred to as signal extender circuit board 24, but circuit function board 24 is not limited to being a signal extender circuit board.

In an example of FIG. 5, DSUB connector-to-circuit board-to ribbon cable adapters 26 included on adapter boards 27 engage with signal ports in, for example, an avionics rack to transfer signals output from the signal ports of the avionics rack through ribbon cables 28 via ribbon cable connectors 29 to ports 18 in front PCB 8. However, adapters 26 are not limited to DSUB connectors and may include cannon plugs, MOLEX connectors, and/or other types of connectors and various combinations of connectors. Connectors included in signal access extender apparatus 10 may be of any type included in the unit which signal access extender apparatus 10 is (temporarily) replacing in compartment 2.

In the example of FIG. 5, one end of signal extender circuit board 24 fastens to rackmount enclosure 12 at rim 13.

In an example, avionics units are wired using 10 different size DSUB connectors: 9 pin, 15 pin SD, 15 pin HD, 25 pin, 26 pin, 37 pin, 44 pin, 50 pin, 62 pin, or 78 pin. Signal access extender apparatus 10 may connect with any or all of the 10 different size DSUB connectors. For each of the 10 different size DSUB connectors, In the present disclosure custom circuit boards adapt field wired DSUB connectors to a corresponding custom circuit board, and wiring from the corresponding custom circuit board is then converted to a standard ribbon cable connector to plug a corresponding ribbon cable into the DSUB connector of the DSUB connector-to-circuit board-to ribbon cable adapter 26 and carry the signals where desired. For manual signal testing, the signals from the harness 5 of the avionics rack are carried by the corresponding ribbon cable to the front PCB 8.

Front PCB 8 shown in FIG. 5 may be a custom PCB that fits on the front of signal access extender apparatus 10. Ports 18 are included on the front side of front PCB 8. On the back (or reverse) side of front PCB 18 are the same DSUB connector-to-circuit board-to ribbon cable adapters 26 as are included on adapter boards 27. Ribbon cables 28 plug into DSUB connector-to-circuit board-to ribbon cable adapters 26 on front PCB 8 and into DSUB connector-to-circuit board-to ribbon cable adapters 26 on adapter boards 27.

Access ports 18 on the front side of front PCB 8 provide connections to the field wired DSUBs (that is, the DSUBs which contact the DSUB connector-to-circuit board-to ribbon cable adapters 26 on adapters 27) arranged in labelled sections and rows based, for example, on connector identification in each avionics units provided by each avionics unit's installation manual. Each labeled connection includes a thru-hole in the front PCB forming a respective access port 18. A user, such as a technician, may insert a meter lead of manual tester 6, for example, into one of the access ports 18 and, thus, into the thru hole, or may hold the meter lead against the access port 18 to make contact and perform a continuity check of access port 18 through DSUB connector-to-circuit board-to ribbon cable adapters 26 on the front PCB 8 to ribbon cable 28 then to DSUB connector-to-circuit board-to ribbon cable adapters 26 on adapter board 27 and signals delivered to the avionics rack.

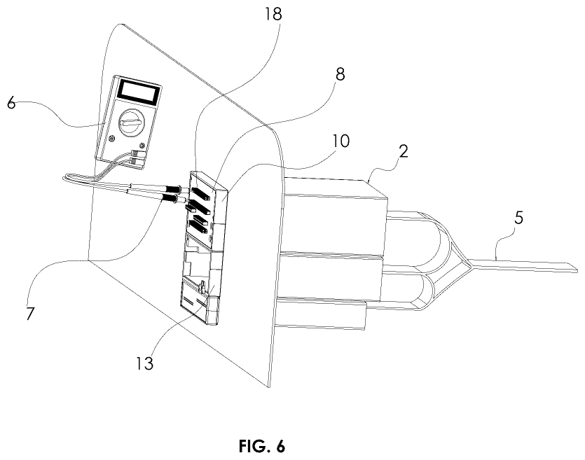

FIG. 6 shows an example of an aircraft instrument panel 30 as a front end 3 of rack system 1. As shown in FIG. 6, signal access extender apparatus 10 of the present disclosure is inserted into compartment 2. Meter leads 7 of manual tester 6 may be inserted into ports 18 of front PCB 8 of signal access extender apparatus 10. Signal access extender apparatus 10 of the present disclosure provides access by leads 7 to signals carried on harness 5 mating with the back end of compartment 2. An example of signals carried on harness 5 include electrical signals, but may also include other types of signals.

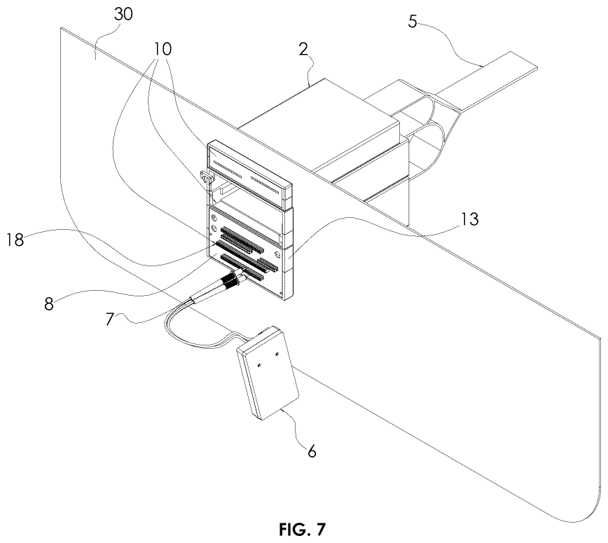

FIG. 7 shows another example of an aircraft instrument panel 30 as a front end 3 of rack system 1. As shown in FIG. 6, signal access extender apparatus 10 of the present disclosure is inserted into compartment 2. Leads 7 of manual tester 6 are inserted into ports 18 of front PCB 8 of signal access extender apparatus 10. Signal access extender apparatus 10 of the present disclosure provides access by leads 7 to signals carried on harness 5 mating with the back end of compartment 2.

As disclosed herein, signal access extender apparatus 10 of the present disclosure slides into a compartment 2 of rack system 1 in place of, for example, an avionics unit. The signal access extender apparatus 10 may mate with connectors of harness 5 that may be installed in a back plate of rack system 1, such as an avionics rack. Once signal access extender apparatus 10 of the present disclosure is slid in place in compartment 2 and the connectors 26 have been mated with connectors of harness 5, the signal from harness 5 will travel through ribbon cable 28 to front PCB 8, thus allowing a user such as a technician to access any of the wiring delivered to compartment 2 by harness 5.

To determine dimensions for signal access extender apparatus 10 to fit into compartment 2, a 3-dimensional (3-D) scan is made of a unit (for example, an avionics unit) which signal access extender apparatus 10 is (temporarily) replacing in compartment 2 and data from the 3-D scan is saved into a 3-D data file. The data from the 3-D data file is then used to 3-D print signal access extender apparatus 10 on a 3-D printer, which signal access extender apparatus 10 is then dry-fit into compartment 2. Iterative adjustments to tolerances in the data between signal access extender apparatus 10 and compartment 2 are then made, and signal access extender apparatus 10 is re-printed using a 3-D printer until signal access extender apparatus 10 fits into a substantially fills compartment 2 and substantially emulates and clones the outer dimensions of the unit which signal access extender apparatus is (temporarily) replacing in compartment 2.

Advantageously, signal access extender apparatus 10 including circuit function board 24 as a signal extender circuit board may assist in ensuring compliance with regulatory requirements and requirements of avionics unit manufacturers and third-party tooling, either while signal access extender apparatus 10 is inserted into compartment 2 of rack system 1 or while harness 5 is plugged into circuit function board 24 on a test bed or test bench. Such regulatory requirements and requirements of avionics unit manufacturers may be set forth in a Supplemental Type Certificate (STC) to ensure point-to-point continuity of signals output from harness 5 and to resolve faults including shorts to ground and/or other issues related to wiring discrepancies prior to installation of avionics units.

By way of another example, circuit function board 24 included in signal access extender apparatus 10 may include automatic testing of continuity of pins and signals, such as electrical signals and including power and ground, output from harness 5 to assist in ensuring compliance with the regulatory requirements and requirements of avionics unit manufacturers and third-party tooling, either while signal access extender apparatus 10 is inserted into compartment 2 of rack system 1 or while harness 5 is plugged into circuit function board 24 on a test bed or test bench. With such automatic testing, signal access extender apparatus 10 may test each pin (such as pin 1, then pin 2, then pin 3, etc.) against every other pin in, for example, a DSUB connector included on circuit function board 24, may also include a WiFi and/or Bluetooth enabled communication port to transmit data to and receive data from a wired or wireless device such as a smartphone, tablet computer, laptop computer, or desktop computer for visual connections. Access ports 18 of front PCB 8 may then be replaced by lights indicating the status of testing and connectivity of various pins of harness 5.

Further, as shown in FIGS. 1 and 6, multiple signal access extender apparatuses 10 may be inserted into multiple corresponding compartments 2 of rack system 1 to test and map continuity of pins and signals, such as electrical signals, included in harness 5 inserted into corresponding compartments 2 or throughout rack system 1. Each signal access extender apparatus 10 may also include a WiFi and/or Bluetooth enabled communication port to transmit data to and receive data from a wired or wireless device such as a smartphone, tablet computer, laptop computer, or desktop computer for visual connections, such data including a map of the continuity of pins and signals included in multiple harnesses 5 respectively inserted into corresponding compartments 2. Each circuit function board 24 included in each signal access extender apparatus 10 may include a communication port, such as a WiFi and/or Bluetooth enabled communication port, to transmit data from the respective circuit function board 24 to computer application software executed on the smartphone, tablet computer, laptop computer, or desktop computer to depict a wiring diagram of the pins and signals throughout rack system 1.

Advantageously, the signal access extender apparatus 10 disclosed herein reduces or eliminates aircraft maintenance downtime and, thus, reduces the cost of aircraft maintenance.

Although a few embodiments have been shown and described, it would be appreciated by those skilled in the art that changes may be made in these embodiments without departing from the principles and spirit of the invention, the scope of which is defined in the claims and their equivalents.

What is claimed is:

1. A signal access extender apparatus comprising:
a rackmount enclosure;
a rackmount enclosure lid coupled to the rackmount enclosure, the rackmount enclosure and the rackmount enclosure lid defining a shape of the signal access extender apparatus;
a printed circuit board inserted into a front end of the rackmount enclosure;
a circuit function board included in the rackmount enclosure and coupled at one end of the circuit function board to a harness and at another end of the circuit function board to the printed circuit board,
wherein
the signal access extender apparatus being insertable into a compartment of a rack system to replace a unit in the compartment, the shape of the signal access extender apparatus being substantially the same as the unit being replaced and being such that the signal access extender apparatus fits within and substantially fills the compartment, the signal access extender apparatus electronically coupling to the harness and to the printed circuit board.

2. The signal access extender apparatus of claim 1, wherein the circuit function board comprising:
an adapter board coupled to the harness;
a first DSUB connector-to-circuit board-to ribbon cable adapter coupled to the harness through the adapter board;
a second DSUB connector-to-circuit board-to ribbon cable adapter coupled to the adapter board; and
a ribbon cable extending between the first DSUB connector-to-circuit board-to ribbon cable adapter and to the second DSUB connector-to-circuit board-to ribbon cable adapter.

3. The signal access extender apparatus of claim 2, further comprising ports on a front end of the printed circuit board.

4. The signal access extender apparatus of claim 3, wherein the ports are in communication with the ribbon cable via a thru hold and the second DSUB connector-to-circuit board-to ribbon cable adapter.

5. The signal access extender apparatus of claim 4, wherein the rack system includes an instrument panel and the signal access extender board provides electronic connection between the instrument panel and the harness of the rack system.

6. The signal access extender apparatus of claim 1, wherein the rackmount enclosure lid is coupled to the rackmount enclosure by fasteners and inserts located on either side of the rackmount enclosure.

7. The signal access extender apparatus of claim 3, wherein the ports on the front end of the printed circuit board are electronically connected to the harness.

8. The signal access extender apparatus of claim 3, wherein the ports are organized by row and by section.

9. A testing system for aircraft electronics, comprising:
a rackmount enclosure;
a rackmount enclosure lid coupled to the rackmount enclosure, the rackmount enclosure and the rackmount enclosure lid defining a shape of the testing system;
a printed circuit board inserted into a front end of the rackmount enclosure;
a circuit function board included in the rackmount enclosure and coupled at one end of the circuit function board to a harness and at another end of the circuit function board to the printed circuit board,
wherein
the testing system being insertable into a compartment of a rack system to replace a unit in the compartment, the shape of the testing being substantially the same as the unit being replaced and being such that the testing system fits within and substantially fills the compartment, the testing system electronically coupling to the harness and to the printed circuit board.

10. The testing system as in claim 8, wherein the printed circuit board comprises ports and the test system further comprising a digital multimeter accessing the ports to perform a continuity test of the aircraft electronics.

11. The testing system of claim 9, wherein the circuit function board comprising:
an adapter board coupled to the harness;
a first DSUB connector-to-circuit board-to ribbon cable adapter coupled to the harness through the adapter board;
a second DSUB connector-to-circuit board-to ribbon cable adapter coupled to the adapter board; and
a ribbon cable extending between the first DSUB connector-to-circuit board-to ribbon cable adapter and to the second DSUB connector-to-circuit board-to ribbon cable adapter.

12. The testing system of claim 10, further comprising ports on a front end of the printed circuit board.

13. The testing system of claim 11, wherein the ports are in communication with the ribbon cable via a thru hold and the second DSUB connector-to-circuit board-to ribbon cable adapter.

14. The testing system of claim 12, wherein the rack system includes an instrument panel and the signal access extender board provides electronic connection between the instrument panel and the harness of the rack system.

15. The testing system of claim 9, wherein the rackmount enclosure lid is coupled to the rackmount enclosure by fasteners and inserts located on either side of the rackmount enclosure.

16. The testing system apparatus of claim 11, wherein the ports on the front end of the printed circuit board are electronically connected to the harness.

17. The testing system apparatus of claim 11, wherein the ports are organized by row and by section.

18. A system comprising:
a first signal access extender apparatus comprising:
a rackmount enclosure;
a rackmount enclosure lid coupled to the rackmount enclosure, the rackmount enclosure and the rackmount enclosure lid defining a shape of the first signal access extender apparatus;
a printed circuit board inserted into a front end of the rackmount enclosure;
a circuit function board included in the rackmount enclosure and coupled at one end of the circuit function board to a harness and at another end of the circuit function board to the printed circuit board,
wherein
the first signal access extender apparatus being insertable into a compartment of a rack system to replace a unit in the compartment, the shape of the first signal access extender apparatus being substantially the same as the unit being replaced and being such that the first signal access extender apparatus fits within and substantially fills the compartment, the first signal access extender apparatus electronically coupling to the harness and to the printed circuit board; and
a second signal access extender apparatus comprising:
a rackmount enclosure;
a rackmount enclosure lid coupled to the rackmount enclosure, the rackmount enclosure and the rackmount enclosure lid defining a shape of the first signal access extender apparatus;
a printed circuit board inserted into a front end of the rackmount enclosure;
a circuit function board included in the rackmount enclosure and coupled at one end of the circuit function board to a harness and at another end of the circuit function board to the printed circuit board,
wherein
the second signal access extender apparatus being insertable into a compartment of a rack system to replace a unit in the compartment, the shape of the second signal access extender apparatus being substantially the same as the unit being replaced and being such that the second signal access extender apparatus fits within and substantially fills the compartment, the second signal access extender apparatus electronically coupling to the harness and to the printed circuit board,
the shape of the first signal access extender apparatus being different than the shape of the second signal access extender apparatus.

19. The system of claim 18, wherein each circuit function board comprising:
an adapter board coupled to the harness;
a first DSUB connector-to-circuit board-to ribbon cable adapter coupled to the harness through the adapter board;
a second DSUB connector-to-circuit board-to ribbon cable adapter coupled to the adapter board; and
a ribbon cable extending between the first DSUB connector-to-circuit board-to ribbon cable adapter and to the second DSUB connector-to-circuit board-to ribbon cable adapter.

20. The system of claim 19, further comprising ports on the front end of each printed circuit board.
